(19) United States
(12) Patent Application Publication
(10) Pub. No.: US 2006/0176757 A1
(43) Pub. Date: Aug. 10, 2006

(54) High performance CMOS NOR predecode circuit

(75) Inventors: Yuen H. Chan, Poughkeepsie, NY (US); Uma Srinivasan, Poughkeepsie, NY (US); Jatinder K. Wadhwa, Wappingers Falls, NY (US)

Correspondence Address: Lynn L. Augspurger;IBM Corporation, 2455 South Road, P386, Poughkeepsie, NY, 12601, US

(73) Assignee: International Business Machines Corporation, Armonk, NY (US)

(21) Appl. No.: 11/054,147

(22) Filed: Feb. 9, 2005

(51) Int. Cl. G11C 8/00

(52) U.S. Cl. 365/230.06

(57) ABSTRACT

A CMOS decoder with an FET stack coupled to the input node so that when all the inputs are selected, the FET stack is conducting and initially holds the value on the input node, and prevents dipping of the input node voltage.

### CROSS REFERENCE TO RELATED APPLICATIONS

This application contains subject matter that is related to the subject matter of the following co-pending applications, each of which is assigned to the same assignee as this application, International Business Machines Corporation of Armonk, N.Y., and is filed concurrently herewith. Each of the below listed applications is hereby incorporated herein by reference. High Speed Domino Bit Line Interface Early Read and Noise Suppression, Attorney Docket POU9 2004 0217; Global Bit Select Circuit With Dual Read and Write Bit Line Pairs, Attorney Docket POU9 2004 0214; Local Bit Select Circuit With Slow Read Recovery Scheme, Attorney Docket POU9 2004 0224; Global Bit Line Restore Timing Scheme and Circuit, Attorney Docket POU9 2004 1234; Local Bit Select With Suppression, Attorney Docket POU9 2004 0246.

### BACKGROUND OF THE INVENTION

1. Field of the Invention

This invention relates to an improved decode circuit using CMOS implemented NOR logic, and more particularly to a circuit for rapidly decoding addresses in a Static Random Memory (SRAM).

2. Description of Background

As will be appreciated by those skilled in the art, the performance of a high speed SRAM can be limited by the performance of its address decoders. In certain SRAM designs, as soon as a particular row of cells is selected by the corresponding word line going high, the bit lines begin to develop a voltage based on the contents of the memory cells. The sooner the word line goes high, the better the read performance of the SRAM. Hence, speed up in the operation of the address decoders results in a better performance of the memory array.

In certain SRAM designs, address decoding is accomplished in two stages, a predecode stage and a second level decode stage. A prior art low active nor logic SRAM address pre-decoder is shown in FIG. 1. The address inputs b0, b1, and b2 are coupled to the gates of decode NFETs n0, n1, and n2 respectively. The drain of each of these NFETs is coupled to an input node 1, which is coupled to the gate of another decode transistor NFET n5. NFET n5 switches from a non-conducting to a conducting state in response to a low select input to all the decode transistors n0, n1, and n2 while the clock signal clk is in its low active state. When the clock input is in its standby state, node 1 and node 2 are pre-charged high by PFETs p1 and p3. The state of node 2 determines the output of the decoder, and the speed at which n5 switches determines the speed at which node 2 changes. In standby state, node 2 is high, output of the decoder is pulled low by the driving NFET n6. The feedback PFET p2 is OFF and p5 is ON. In active state, the inputs at b0-b2 switch and settle to a stable level before the clock clk is activated. Once the clock input clk assumes its active state, node clc goes high, turning off the pre-charge devices p1 and p3, and turning on driver n4. Nodes 1 and 2 float for a brief period of time, until n4 starts conducting. Conduction through n4 pulls down node 3 which in turn pulls down node 2 since NFET n5 is conducting as a result of node 1 having been pre-charged high and the decode devices n0-n2 having been turned off (for a fully decoded case). Due to the capacitive coupling between the gate and source of PFET 2 and between the gate and source of NFET 5, there is a dip in the voltage of node 1 when node 2 and node 3 are pulled down. This transient dipping of node 1 in effect reduces the gate voltage of n5, hence its effective strength in driving the output and its switching speed are degraded. After node 2 is pulled low by n5, the feedback PFET p2 is then turned on to recover the dipping node 1 back to a high level. At the same time, the output PFET p6 is turned on to pull the decoder output to a high level.

### SUMMARY OF THE INVENTION

An object of this invention is the provision of an SRAM CMOS decoder that provides a high switching speed.

Briefly, this invention contemplates the provision of a CMOS decoder with an FET stack coupled to the input node so that when all the inputs are selected, the FET stack is conducting and initially holds the value on the input node, and prevents dipping of the input node voltage.

### BRIEF DESCRIPTION OF THE DRAWINGS

The subject matter that is regarded as the invention is particularly pointed out and distinctly claimed in the claims at the conclusion of the specification. The forgoing and other objects, features, and advantages of the invention are apparent from the following detailed description taken in conjunction with the accompanying drawings in which:

FIG. 1 is a schematic diagram of a prior art decoder of the type to which the teachings of this invention apply.

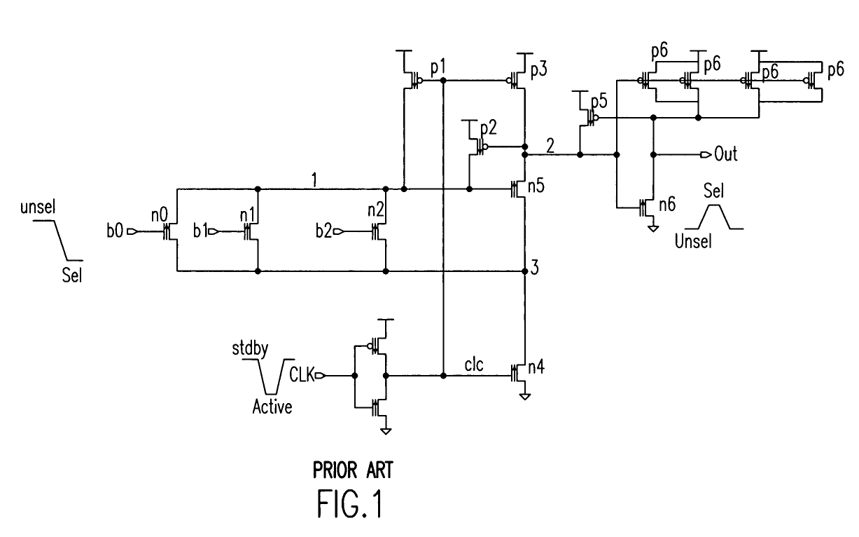

FIG. 2 is a schematic diagram of one embodiment of an encoder in accordance with the teachings of this invention.

### DETAILED DESCRIPTION OF THE INVENTION

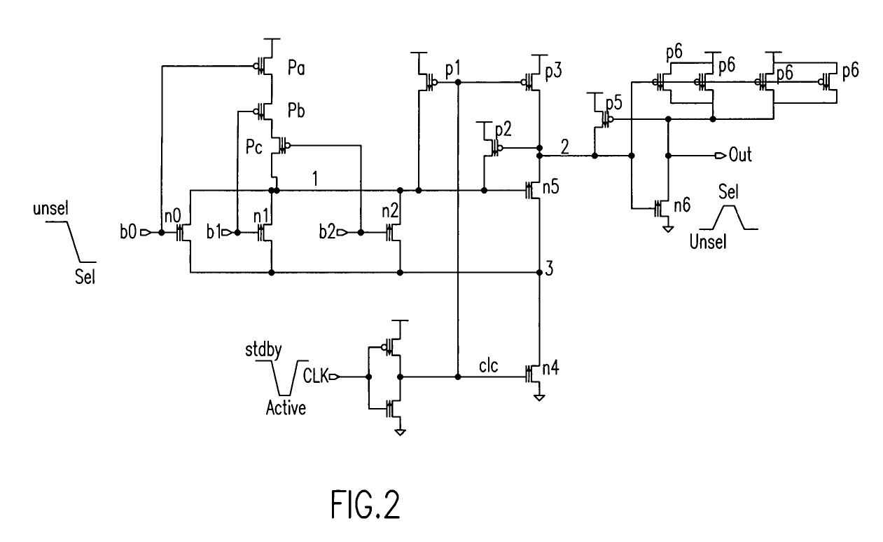

Referring now to FIG. 2, three PFETs (Pa, Pb, and Pc) coupled in a series stack between the input node 1 and the decoder supply voltage Vdd. The gates of Pa, Pb and Pc are coupled respectively to the decoder inputs b1, b2, and b3. Thus it will be appreciated, that when all three inputs are selected, the transistors of the series stack Pa, Pb, and Pc are all forwardly biased and connect node 1 to the supply voltage Vdd, thus holding node 1 high, and reducing the dip in node 1 caused by the capacitive coupling in transistors P2 and N5 described above. With the PFET stack added, the input stage (consisting of decoding devices Pa, Pb, Pc and n0-n2) now fully forms a 3-input NOR decode structure to drive the rest of the decoder circuit, which operates in dynamic fashion. As a result, the noise glitch seen on the decoding node (node 1) is much reduced. The decoder's switching performance is greatly improved.

While the preferred embodiment of the invention has been described, it will be understood that those skilled in the art, both now and in the future, may make various improvements and enhancements which fall within the scope of the claims which follow. These claims should be construed to maintain the proper protection for the invention first described.

1-2. (canceled)

3. A low active NOR decoder for decoding SRAM addresses comprising in combination:
a plurality of low select address inputs coupled respectively to the gates of a plurality of N-type field effect decode transistors with the drains of said plurality of N-type field effect transistors coupled to the gate of an N-type field effect transistor;
said N-type field effect transistor switching from a non-conducting state to a conducting state in order to pull down a pre-charged high node in response to a low select address input to all address inputs in combination with an active clock signal input; and
a circuit to pull up said gate in response to a select input to all of said plurality of low select address inputs.

4. A low active NOR decoder as in claim 3, wherein said circuit includes a plurality of P-type of field effect transistors connected in series between a pull up voltage source and said gate.

5. A low active NOR decoder as in claim 4, wherein there is one of said P-type field effect transistors for each of said plurality of N-type field effect transistors.

6. A low active NOR decoder as in claim 3, further including a feedback transistor to pull up said gate of said N-type field effect transistor coupled between said node and said gate.

7. A low active NOR decoder as in claim 4, wherein a gate of each of said plurality of P-type field effect transistors is coupled respectively to one of said plurality of low select address inputs.

8. A low active NOR decoder as in claim 3, wherein a select address input causes an addressed field effect transistor to switch from a conducting state to a non-conducting state.

9. A low active NOR decoder as in claim 8, wherein said circuit includes a plurality of P-type of field effect transistors connected in series between a pull up voltage source and said gate.

10. A low active NOR decoder as in claim 8, further including a feedback transistor to pull up said gate of said N-type field effect transistor coupled between said node and said gate.

11. A NOR decoder comprising in combination:
a plurality of address inputs coupled respectively to a plurality of field effect decode transistors with a select address input to each of said plurality of field effect decode transistors causing respectively each of said field effect decode transistors to switch from a conducting state to a non-conducting state;
said plurality of field effect decode transistors coupled to the gate of a field effect transistor that switches from a non-conducting state to a conducting state in order to pull down a pre-charged high node in response to a select input to all address inputs in combination with an active clock signal input; and
means to pull up said gate in response to a select input to the address inputs of all of said plurality of field effect decode transistors.

12. A NOR decoder as in claim 11, further including feedback means to pull up said gate after said field effect transistor switches from a non-conducting state to a conducting state.

13. A NOR decoder as in claim 11, wherein said means to pull up said gate includes a series stack of field effect transistors.

14. A NOR decoder as in claim 12, wherein said means to pull up said gate includes a series stack of field effect transistors.

15. A NOR decoder as in claim 13, wherein the gates of the transistors in said series stack of field effect transistors are coupled respectively to said plurality of address inputs.

16. A NOR decoder as in claim 14, wherein the gates of the transistors in said series stack of field effect transistors are coupled respectively to said plurality of address inputs.

17. A NOR decoder as in claim 15, wherein a select input address input to all of said address inputs causes said series stack of field effect transistors to pull up said gate.

18. A NOR decoder as in claim 16, wherein a select input address input to all of said address inputs causes said series stack of field effect transistors to pull up said gate.

19. A method for improving the performance of low active NOR decoder for decoding SRAM addresses in which a plurality of low select address inputs are coupled respectively to the gates of a plurality of N-type field effect decode transistors with the drains of said plurality of N-type field effect transistors coupled to the gate of an N-type field effect transistor that switches from a non-conducting state to a conducting state in order to pull down a pre-charged high node in response to a select input to all address inputs in combination with an active clock signal input including the step of pulling up said gate in response to a select input to all of said plurality of low select address inputs.

20. A method as in claim 19, wherein said pulling up step includes turning on transistors in a series connected stack of transistors connected to a pull up voltage source.

21. (canceled)

22. A method as in claim 21, wherein said series connected stack of transistors is turned on in response to a low select address signal input.
